(19) United States
(12) Patent Application Publication
(10) Pub. No.: US 2025/0069657 A1
(43) Pub. Date: Feb. 27, 2025

(54) Repair Method in Phase Change Storage Apparatus, Phase Change Storage Apparatus, and Electronic Device

(71) Applicant: Huawei Technologies Co., Ltd., Shenzhen (CN)

(72) Inventors: Sa Tu, Wuhan (CN); Yifeng Chen, Shanghai (CN)

(21) Appl. No.: 18/941,629

(22) Filed: Nov. 8, 2024

Related U.S. Application Data
(63) Continuation of application No. PCT/CN2023/094032, filed on May 12, 2023.

(30) Foreign Application Priority Data
May 13, 2022 (CN) 202210522392.2

(51) Int. Cl. G11C 13/00; G11C 29/44; H10B 63/10

(52) U.S. Cl. CPC G11C 13/0033; G11C 13/0004; G11C 13/0069; G11C 13/0097; G11C 29/44; H10B 63/10; G11C 13/004; G11C 2013/0078

(57) ABSTRACT

A method includes determining that a target phase change storage unit needs to be repaired for failure, and applying a repair pulse to the target phase change storage unit, where a polarity of the repair pulse is opposite to a polarity of a standard write operation pulse and a polarity of a standard erase operation pulse of the target phase change storage unit, and where an amplitude of the repair pulse is greater than an amplitude of the standard write operation pulse and an amplitude of the standard erase operation pulse.

### CROSS-REFERENCE TO RELATED APPLICATIONS

This is a continuation of International Patent Application No. PCT/CN2023/094032, filed on May 12, 2023, which claims priority to Chinese Patent Application No. 202210522392.2, filed on May 13, 2022, and the disclosures of the aforementioned applications are hereby incorporated by reference.

### TECHNICAL FIELD

This disclosure relates to the field of storage technologies, and in particular, to a repair method in a phase change storage apparatus, a phase change storage apparatus, and an electronic device.

### BACKGROUND

A basic principle of a phase-change memory (PCM) is to make a phase change material undergo a reversible phase change between an amorphous state and a crystalline state through an electrical pulse signal acting on a device unit, and to store data by using a conductivity difference of the phase change material during conversion between the amorphous state and the crystalline state. Throughout an effective operation life cycle of the PCM, operation conditions of read, write, and erase usually remain unchanged. However, with an increase in a quantity of operations, a characteristic of the phase change material gradually changes, an operation condition of a storage unit gradually drifts, and an original fixed operation condition may be over-operated, resulting in premature device failure and reduced fatigue life.

The phase change material exhibits a low-resistance state, also referred to as a “set” state, in the crystalline state, and a corresponding logical value of the storage unit is “0”. The phase change material exhibits a high-resistance state, also referred to as a “reset” state, in the amorphous state, and a corresponding logical value of the storage unit is “1”. Fatigue failure modes mainly include two modes. One is set stuck, where in an operation process of the phase change storage unit, a resistance value is fixed in a low-resistance state and cannot be changed to a high-resistance state. This failure mode is usually caused by segregation, for example, is caused by uneven distribution of elements inside the phase change material during crystallization. The other is “rst stuck”, where in an operation process of the phase change storage unit, a resistance value is fixed in a high-resistance state and cannot be changed to a low-resistance state. This failure mode is usually caused by a void in elements inside the phase change material.

Although there is a repair method for the set stuck failure mode and a repair method for the rst stuck failure mode, each repair method can only be used to resolve a problem of one fatigue failure, and cannot resolve problems of two fatigue failures. The PCM includes a phase change storage unit array including a plurality of phase change storage units. After performing a plurality of read, write, and erase operations on the PCM, some phase change storage units may enter the set stuck failure mode, and some phase change storage units may enter the rst stuck failure mode. Therefore, the repair method that can only resolve a problem of a single failure mode cannot meet a current requirement.

### SUMMARY

This disclosure provides a repair method in a phase change storage apparatus, a phase change storage apparatus, and an electronic device, so that a failure of a set stuck mode and a failure of a rst stuck mode can both be repaired.

According to a first aspect, this disclosure provides a repair method in a phase change storage apparatus. The phase change storage apparatus includes a plurality of phase change storage units. The method includes determining a target phase change storage unit that needs to be repaired in the phase change storage apparatus; and applying a repair pulse to the target phase change storage unit, where a polarity of the repair pulse is opposite to polarities of a standard write operation pulse and a standard erase operation pulse of the target phase change storage unit, an amplitude of the repair pulse is greater than an amplitude of the standard write operation pulse and an amplitude of the standard erase operation pulse, and a pulse width of the repair pulse is not greater than a pulse width of the standard write operation pulse and a pulse width of the standard erase operation pulse.

In this embodiment of this disclosure, because the polarity of the repair pulse is opposite to the polarity of the standard write operation pulse and the polarity of the standard erase operation pulse, a failure problem of the set stuck mode can be resolved. In addition, because the amplitude of the repair pulse is greater than the amplitude of the standard write operation pulse and the amplitude of the standard erase operation pulse, and the pulse width of the repair pulse is not greater than the pulse width of the standard write operation pulse and the pulse width of the standard erase operation pulse, a failure problem of the rst stuck mode can be resolved by applying a fast high current pulse to the phase change storage unit. In an example, the phase change storage apparatus in this embodiment of this disclosure can resolve both the failure problem of the set stuck mode and the failure problem of the rst stuck mode. For a phase change storage unit array including a plurality of phase change storage units, a failure problem of the set stuck mode and a failure problem of the rst stuck mode, which may occur, can be better resolved.

In a possible implementation, determining a target phase change storage unit that needs to be repaired in the phase change storage apparatus includes obtaining a first parameter value of the target phase change storage unit; comparing the first parameter value with a preset parameter value; and determining, when a result of comparison between the first parameter value and the preset parameter value satisfies a repair condition, that the target phase change storage unit is the target phase change storage unit that needs to be repaired. After the phase change storage unit is used for a plurality of times, a parameter value of the phase change storage unit may drift. The parameter value of the phase change storage unit when undergoing a fatigue failure or close to a fatigue failure may be used as a preset parameter threshold, to determine, based on a result of comparison between a current parameter value of the phase change storage unit and the preset parameter value, whether the phase change storage unit needs to be repaired.

In a possible implementation, the first parameter value is an electrical parameter value of the target phase change storage unit when a write operation or an erase operation is performed on the target phase change storage unit, and the preset parameter value is a preset electrical parameter threshold. After the phase change storage unit is used for a plurality of times, an electrical parameter of the phase change storage unit may drift. The electrical parameter of the phase change storage unit when undergoing the fatigue failure or close to the fatigue failure may be used as a preset electrical parameter threshold. In an example, when the electrical parameter of the phase change storage unit deviates to the preset electrical parameter threshold, it may be determined that the phase change storage unit is close to the fatigue failure and needs to be repaired.

In a possible implementation, the electrical parameter value is a write voltage, a write current, or resistance of the target phase change storage unit when the write operation is performed, or an erase voltage, an erase current, or resistance of the target phase change storage unit when the erase operation is performed. After the phase change storage unit is used for a plurality of times, the voltage, the current, and the resistance of the write operation/erase operation performed on the phase change storage unit drift, and may become larger or smaller. When the actual voltage, current, and resistance increase or decrease to a preset threshold, it may be determined that the phase change storage unit is close to the fatigue failure and needs to be repaired.

In a possible implementation, the first parameter value is a success rate of a pre-operation on the target phase change storage unit, and the preset parameter value is a preset success rate threshold. The pre-operation may include a pre-write operation and/or a pre-erase operation. The pre-write operation indicates a write operation performed on a phase change storage unit based on a pre-write operation pulse, and a voltage of the pre-write operation pulse is less than a voltage of the standard write operation pulse. The pre-erase operation indicates an erase operation performed on a phase change storage unit based on a voltage of the pre-erase operation, and the voltage of the pre-erase operation is determined based on a voltage of the standard erase operation and is less than the voltage of the standard erase operation. If a voltage of the pre-write operation and/or a voltage of the pre-erase operation are/is set properly, when the phase change storage unit does not undergo the fatigue failure or is not close to the fatigue failure, a write operation/an erase operation can be successfully implemented by applying the voltage of the pre-write operation/the voltage of the pre-erase operation to the phase change storage unit. Based on this, if the success rate of the pre-operation is less than or equal to the success rate threshold, it indicates that the phase change storage unit may undergo the fatigue failure or be close to the fatigue failure, and needs to be repaired.

In a possible implementation, the first parameter value is a quantity of operations on the target phase change storage unit, and the preset parameter value is a preset threshold of the quantity of operations. That the fatigue failure occurs in the phase change storage unit is positively correlated with the quantity of operations performed on the phase change storage unit. In other words, the greater the quantity of operations performed, the higher a probability that the fatigue failure occurs in the phase change storage unit. In an example, in this implementation, it may be determined, based on the quantity of operations performed on the target phase change storage unit, whether the target phase change storage unit needs to be repaired.

In a possible implementation, the quantity of operations includes a quantity of write operations, a quantity of erase operations, or a sum of the quantity of write operations and the quantity of erase operations.

According to a second aspect, this disclosure provides a phase change storage apparatus, including: a phase change storage unit array, a selecting module, a repair module, and a pulse generator. The phase change storage unit array includes a plurality of phase change storage units. The repair module is configured to: determine a target phase change storage unit that needs to be repaired in the phase change storage unit array, select the target phase change storage unit using the selecting module, and control the pulse generator to apply a repair pulse to the target phase change storage unit, where a polarity of the repair pulse is opposite to a polarity of a standard write operation pulse and a polarity of a standard erase operation pulse of the target phase change storage unit, an amplitude of the repair pulse is greater than an amplitude of the standard write operation pulse and an amplitude of the standard erase operation pulse, and a pulse width of the repair pulse is not greater than a pulse width of the standard write operation pulse and a pulse width of the standard erase operation pulse.

In a possible implementation, the repair module, when determining the target phase change storage unit that needs to be repaired in the phase change storage unit array, is configured to obtain a first parameter value of the target phase change storage unit; compare the first parameter value with a preset parameter value; and determine, when a result of comparison between the first parameter value and the preset parameter value satisfies a repair condition, that the target phase change storage unit is the target phase change storage unit that needs to be repaired.

In a possible implementation, the first parameter value is an electrical parameter value of the target phase change storage unit when a write operation or an erase operation is performed on the target phase change storage unit, and the preset parameter value is a preset electrical parameter threshold.

In a possible implementation, the electrical parameter value is a write voltage, a write current, or resistance of the target phase change storage unit when the write operation is performed, or an erase voltage, an erase current, or resistance of the target phase change storage unit when the erase operation is performed.

In a possible implementation, the first parameter value is a success rate of a pre-operation on the target phase change storage unit, and the preset parameter value is a preset success rate threshold. The success rate of a pre-operation includes a success rate of a pre-write operation and/or a success rate of a pre-erase operation. The pre-write operation indicates a write operation performed on a phase change storage unit based on a pre-write operation pulse, and a voltage of the pre-write operation pulse is less than a voltage of the standard write operation pulse. The pre-erase operation indicates an erase operation performed on a phase change storage unit based on a voltage of the pre-erase operation, and the voltage of the pre-erase operation is determined based on a voltage of the standard erase operation and is less than the voltage of the standard erase operation.

In a possible implementation, the first parameter value is a quantity of operations on the target phase change storage unit, and the preset parameter value is a preset threshold of the quantity of operations.

In a possible implementation, the quantity of operations includes a quantity of write operations, a quantity of erase operations, or a sum of the quantity of write operations and the quantity of erase operations.

According to a third aspect, this disclosure provides an electronic device, including a processor and the phase change storage apparatus provided in any one of the second aspect, where the processor is configured to write data to the phase change storage apparatus or read data from the phase change storage apparatus.

According to a fourth aspect, this disclosure provides a memory chip. The memory chip includes a control circuit, a phase change storage unit array, and a pulse generator. The control circuit is configured to execute instructions, and the instructions instruct to implement the method according to any one of the first aspect or the implementations of the first aspect on the phase change storage unit array.

### BRIEF DESCRIPTION OF DRAWINGS

FIG. 1 is a schematic diagram of a structure of a phase change storage apparatus according to an embodiment of this disclosure;

FIG. 2 is a schematic diagram of a structure of a phase change storage unit;

FIG. 3 is a schematic diagram of a structure of another phase change storage unit;

FIG. 4 is a schematic diagram of a pulse according to an embodiment of this disclosure;

FIG. 5 is a schematic diagram of a repair pulse according to an embodiment of this disclosure;

FIG. 6 is a schematic diagram of composition of a failure mode according to an embodiment of this disclosure;

FIG. 7 is a schematic diagram of a quantity of fatigue operations and a probability of a failure according to an embodiment of this disclosure; and

FIG. 8 is a schematic flowchart of a phase change storage unit repair method according to an embodiment of this disclosure.

### DESCRIPTION OF EMBODIMENTS

For a failure problem of a set stuck mode of a PCM, one repair method is to apply a reverse repair current pulse to a failed phase change storage unit, and a pulse width of the reverse repair current pulse is greater than or equal to a smaller one between a write operation pulse bandwidth and an erase operation pulse bandwidth. However, the method can only be used to resolve a failure problem of the set stuck mode. Because an amplitude of the reverse repair current pulse is small, and the pulse width is large, an effect of applying a fast high current to the phase change storage unit cannot be achieved. In an example, a failure problem of a rst stuck mode cannot be resolved.

For the failure problem of the rst stuck mode, current solutions include optimizing element doping, high temperature annealing, a fast high current pulse, and the like. Similarly, the foregoing solutions can only resolve a failure problem of one mode. Because the failure problem of the set stuck mode cannot be resolved without applying a reverse pulse, the problems of two failure modes of set stuck and rst stuck modes cannot be both resolved.

In view of this, embodiments of this disclosure provide a phase change storage apparatus. The apparatus can repair a phase change storage unit undergoing a fatigue failure or a phase change storage unit close to a fatigue failure. The apparatus can repair both a failure of the set stuck mode and a failure of the rst stuck mode.

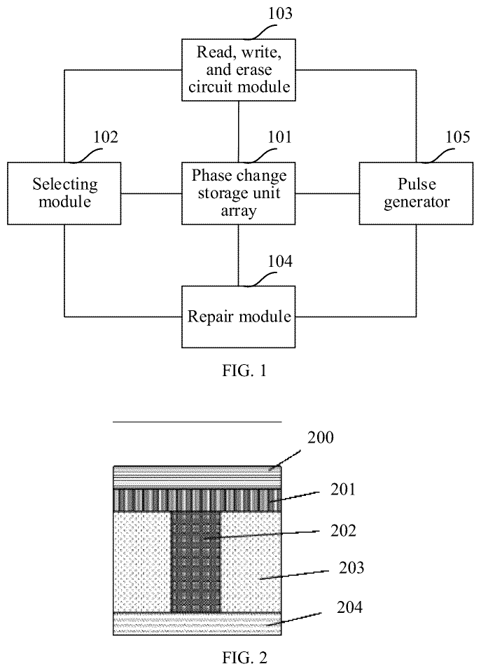

FIG. 1 is a schematic diagram of a structure of a phase change storage apparatus according to an embodiment of this disclosure. As shown in FIG. 1, the storage apparatus includes a phase change storage unit array 101, a selecting module 102, a read, write, and erase circuit module 103 (optional), a repair module 104, and a pulse generator 105.

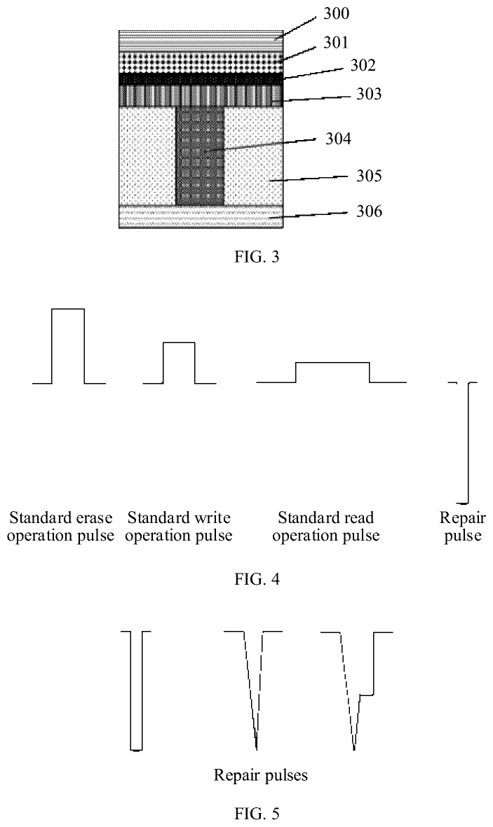

The phase change storage unit array 101 includes a plurality of phase change storage units, and each phase change storage unit includes a PCM material configured to store information, an electrode configured to conduct electricity to the PCM material, and the like. For example, FIG. 2 and FIG. 3 are schematic diagrams of structures of two phase change storage units.

In the phase change storage unit shown in FIG. 2, the phase change storage unit includes a top electrode 200, a PCM material layer 201, a heating electrode 202, a dielectric isolation layer 203, and a bottom electrode 204. The top electrode 200, the heating electrode 202, and the bottom electrode 204 may be made of a material with good conductivity and high thermal stability. The dielectric isolation layer 203 is made of an insulation material. After the top electrode 200 and the bottom electrode 204 are energized, the heating electrode 202 heats the PCM material layer 201, so that the PCM material layer 201 converts between a crystalline state and an amorphous state, thereby achieving data storage.

In the phase change storage unit shown in FIG. 3, the phase change storage unit includes a top electrode 300, an ovonic threshold switch (OTS) material layer 301, a buffer layer 302, a PCM material layer 303, a heating electrode 304, a dielectric isolation layer 305, and a bottom electrode 306. In the phase change storage unit shown in FIG. 3, the additional OTS material layer 301 is integrated with the PCM material layer 303, so that a leakage current of an adjacent unit can be suppressed, to reduce power consumption, improve a readout margin, and expand an array size.

It should be understood that the two phase change storage units shown in FIG. 2 and FIG. 3 are merely examples that can be used in the phase change storage apparatus in embodiments of this disclosure. The phase change storage apparatus in embodiments of this disclosure may alternatively use a phase change storage unit array including phase change storage units of another structure or selectors made of another material.

The selecting module 102 is configured to select a corresponding target phase change storage unit from the plurality of phase change storage units included in the phase change storage unit array 101. For example, when a write operation is performed, a phase change storage unit to which data is to be written is the target phase change storage unit, and the selecting module 102 selects the target phase change storage unit in the phase change storage unit array 101, so that a write operation pulse is applied to the target phase change storage unit, to complete the write operation on the target phase change storage unit. For another example, when a repair operation is performed, a to-be-repaired phase change storage unit is the target phase change storage unit, and the selecting module 102 selects the target phase change storage unit, so that a repair pulse is applied to the target phase change storage unit, to complete the repair operation on the target phase change storage unit.

Optionally, the selecting module 102 may further include a word line decoder and a bit line decoder. The phase change storage unit array 101 may be coupled to the word line decoder through a word line (WL), and coupled to the bit line decoder through a bit line (BL). The word line is a signal line needed to select a row of phase change storage units from the phase change storage unit array. The bit line is a signal line needed to select a column of phase change storage units from the phase change storage unit array. The word line and the bit line work together to complete selection of one or more phase change storage units.

The read, write, and erase circuit module 103 is configured to receive an operation instruction, select a phase change storage unit using the selecting module 102 based on the received operation instruction, and control the pulse generator 105 to apply a read operation pulse, a write operation pulse, or an erase operation pulse to the selected phase change storage unit.

For example, if the operation instruction received by the read, write, and erase circuit module 103 instructs a write operation on a phase change storage unit in the first row and the first column, the read, write, and erase circuit module 103 selects the phase change storage unit in the first row and the first column using the selecting module 102, and controls the pulse generator 105 to generate a write operation pulse, to implement the write operation on the phase change storage unit in the first row and the first column; if the received operation instruction instructs a read operation on a phase change storage unit in the first row and the second column, the read, write, and erase circuit module 103 selects the phase change storage unit in the first row and the second column using the selecting module 102, and controls the pulse generator 105 to generate a read operation pulse, to read data stored in the phase change storage unit in the first row and the second column; or if the received operation instruction instructs an erase operation on a phase change storage unit in the first row and the third column, the read, write, and erase circuit module 103 selects the phase change storage unit in the first row and the third column using the selecting module 102, and controls the pulse generator 105 to generate an erase operation pulse, to implement the erase operation on data stored in the phase change storage unit in the first row and the third column.

The repair module 104 is configured to determine a target phase change storage unit that needs to be repaired in the phase change storage apparatus, select the target phase change storage unit using the selecting module 102, and control the pulse generator 105 to apply a repair pulse to the target phase change storage unit. A polarity of the repair pulse is opposite to a polarity of a standard write operation pulse and a polarity of a standard erase operation pulse of the target phase change storage unit, an amplitude of the repair pulse is greater than an amplitude of the standard write operation pulse and an amplitude of the standard erase operation pulse, and a pulse width of the repair pulse is not greater than a pulse width of the standard write operation pulse and a pulse width of the standard erase operation pulse.

A voltage of the standard write operation pulse may be a pulse voltage applied when a write operation is performed on the phase change storage unit for the first time, may be an average value of pulse voltages applied when a write operation is performed on the phase change storage unit for the first N times (for example, the first 10⁵ times) during an experiment, or may be a voltage of the write operation pulse specified in a specification. Similarly, a current/resistance of the standard write operation may also be a current/resistance when a write operation is performed on the phase change storage unit for the first time, may be an average value of currents/resistance when a write operation is performed on the phase change storage unit for the first N times (for example, the first 10⁵ times) during an experiment, or may be a current/resistance specified in the specification when a write operation pulse is applied.

For example, FIG. 4 is a schematic diagram of a standard write operation pulse, a standard erase operation pulse, a standard read operation pulse, and a repair pulse of a phase change storage unit. In the example shown in FIG. 4, from a perspective of a pulse polarity, the standard write operation pulse, the standard erase operation pulse, and the standard read operation pulse have a same polarity, and may be referred to as forward pulses; and the repair pulse has a polarity opposite to the polarity of the other pulses, and may be referred to as a reverse pulse. From a perspective of a pulse amplitude, an amplitude of the standard erase operation pulse is greater than an amplitude of the standard write operation pulse, and the amplitude of the standard write operation pulse is greater than an amplitude of the standard read operation pulse; and an amplitude of the repair pulse is the largest and greater than the amplitudes of the other operation pulses. From a perspective of a pulse width, a pulse width of the standard erase operation pulse is same as a pulse width of the standard write operation pulse, and a pulse width of the standard read operation pulse is the largest; and a pulse width of the repair pulse is the smallest, less than the pulse widths of the other operation pulses.

It should be understood that FIG. 4 is an example of this disclosure. In an example of the disclosure, another form of pulse can alternatively be used for resolving a technical problem that needs to be resolved in this embodiment of this disclosure. For example, the pulse width of the standard erase operation pulse may be different from the pulse width of the standard write operation pulse. For another example, a waveform of the repair pulse may alternatively be a waveform shown in FIG. 5 or a waveform of another shape.

As mentioned before, in one repair manner for a failure problem of the set stuck mode, a reverse repair current pulse is applied to a failed phase change storage unit, and a pulse width of the reverse repair current pulse is greater than or equal to a smaller one between a write operation pulse bandwidth and an erase operation pulse bandwidth. However, after repeated experiments on a phase change storage unit, an applicant finds that a failure problem of the set stuck mode can be repaired by applying a reverse pulse to the phase change storage unit, and whether a pulse width of the reverse pulse is greater than or equal to the smaller one between the write operation pulse bandwidth and the erase operation pulse bandwidth has no significant impact on an experiment result. In an example, even if the pulse width of the applied reverse pulse is less than both the pulse width of the standard erase operation pulse and the standard write operation pulse, the failure problem of the set stuck mode of the phase change storage unit can still be resolved.

In addition, in this embodiment of this disclosure, the amplitude of the repair pulse is greater than the amplitude of the standard write operation pulse and the amplitude of the standard erase operation pulse, and the pulse width of the repair pulse is not greater than the pulse width of the standard write operation pulse and the pulse width of the standard erase operation pulse. In other words, a fast high current is applied to the phase change storage unit. It is found through experiments that, applying a fast high current to the phase change storage unit can increase a heating temperature of the PCM material layer, facilitating recrystallization of the PCM material layer, thereby repairing a failure problem of the rst stuck mode.

In conclusion, in this embodiment of this disclosure, because the polarity of the repair pulse is opposite to the polarity of the standard write operation pulse and the polarity of the standard erase operation pulse, the failure problem of the set stuck mode can be resolved. In addition, because the amplitude of the repair pulse is greater than the amplitude of the standard write operation pulse and the amplitude of the standard erase operation pulse, and the pulse width of the repair pulse is not greater than the pulse width of the standard write operation pulse and the pulse width of the standard erase operation pulse, the failure problem of the rst stuck mode can be resolved. In an example, the phase change storage apparatus in this embodiment of this disclosure can resolve both the failure problem of the set stuck mode and the failure problem of the rst stuck mode. For a phase change storage unit array including a plurality of phase change storage units, the failure problem of the set stuck mode and the failure problem of the rst stuck mode, which may occur, can be better resolved. In addition, when the phase change storage unit uses the structure shown in FIG. 3, the repair pulse in this embodiment of this disclosure can further play a role of suppressing threshold voltage (Vth) drift of the OTS.

In this embodiment of this disclosure, when determining whether the target phase change storage unit needs to be repaired, the repair module 104 may obtain a first parameter value of the target phase change storage unit, compare the first parameter value with a preset parameter value, and determine, when a result of comparison between the first parameter value and the preset parameter value satisfies a repair condition, that the target phase change storage unit is the phase change storage unit that needs to be repaired. After the phase change storage unit is used for a plurality of times, a parameter value of the phase change storage unit may drift. The parameter value of the phase change storage unit when undergoing a fatigue failure or close to a fatigue failure may be used as the preset parameter value, to determine, based on a result of comparison between a current parameter value of the phase change storage unit and the preset parameter value, whether the phase change storage unit needs to be repaired.

In a possible implementation, the first parameter value may be an electrical parameter value of the target phase change storage unit, and correspondingly, the preset parameter value may be a preset electrical parameter threshold.

For example, the electrical parameter value may be a write voltage, a write current, or resistance of the target phase change storage unit during a write operation, or may be an erase voltage, an erase current, or resistance of the target phase change storage unit during an erase operation. The following describes the foregoing possible implementations by way of example.

Manner 1: The repair module 104 obtains an actual write voltage of the target phase change storage unit when a write operation is performed. If the actual write voltage of the target phase change storage unit is greater than or equal to a first voltage threshold, or is less than or equal to a second voltage threshold, it is determined that the target phase change storage unit needs to be repaired.

As mentioned above, after a plurality of operations on the phase change storage unit, a pulse voltage of the write operation applied to the phase change storage unit may drift, and may become larger or smaller, instead of keeping a voltage of the standard write operation pulse unchanged. As a quantity of operations increases, an absolute value of a difference between the actual write voltage and the voltage of the standard write operation pulse gradually increases. When the actual write voltage increases to the first voltage threshold or decreases to the second voltage threshold, the repair module 104 may determine that the phase change storage unit needs to be repaired.

The first voltage threshold and the second voltage threshold may be determined based on the voltage of the standard write operation pulse. For example, if the voltage of the standard write operation pulse is V_{w}, and a pre-configured voltage drift coefficient is x, the first voltage threshold may be (1+x)V_{w}, and the second voltage threshold may be (1−x)V_{w}. For another example, if the voltage of the standard write operation pulse is V_{w}, and a pre-configured voltage drift value is X, the first voltage threshold may be V_{w}+X, and the second voltage threshold may be V_{w}−X.

The voltage drift coefficient x or the voltage drift value X may be determined based on a voltage of the phase change storage unit when a fatigue failure occurs after repeated operation experiments on the phase change storage unit. For example, if the voltage of the standard write operation pulse of the phase change storage unit is 3 V, an average value of the last actual write voltages of the phase change storage unit before the fatigue failure occurs is 3.3 V; the voltage drift coefficient x may be set to 0.1, and the corresponding obtained first voltage threshold is (1+0.1)*3 V=3.3 V; alternatively, the voltage drift coefficient x may be set to 0.08 (or another value less than 0.1), to predict a case in which the fatigue failure occurs in the phase change storage unit. The phase change storage unit is repaired before the fatigue failure occurs, rather than being repaired after the fatigue failure occurs. This helps reduce occurrence of the fatigue failure in the phase change storage unit, thereby increasing reliability of a device, and ensuring storage performance of the phase change storage apparatus.

Manner 2: The repair module 104 obtains an actual erase voltage of the target phase change storage unit when an erase operation is performed. If the actual erase voltage of the target phase change storage unit is greater than or equal to a third voltage threshold, or is less than or equal to a fourth voltage threshold, it is determined that the target phase change storage unit needs to be repaired.

Similarly, after a plurality of operations on the phase change storage unit, a pulse voltage of the erase operation applied to the phase change storage unit may drift, and may become larger or smaller, instead of keeping a voltage of the standard erase operation pulse unchanged. As a quantity of operations increases, an absolute value of a difference between the actual erase voltage and the voltage of the standard erase operation pulse gradually increases. When the actual erase voltage increases to the third voltage threshold or decreases to the fourth voltage threshold, the repair module 104 may determine that the phase change storage unit needs to be repaired.

The third voltage threshold and the fourth voltage threshold may be determined based on the voltage of the standard erase operation pulse. For example, if the voltage of the standard erase operation pulse is Vₑ, and a pre-configured voltage drift coefficient is y, the third voltage threshold may be (1+y)Vₑ, and the fourth voltage threshold may be (1−y)Vₑ. For another example, if the voltage of the standard erase operation pulse is Vₑ, and a pre-configured voltage drift value is Y, the third voltage threshold may be Vₑ+Y, and the fourth voltage threshold may be Vₑ−Y. A value selection manner of the voltage drift coefficient y or the voltage drift value Y is similar to a value selection manner of the voltage drift coefficient x or the voltage drift value X. Details are not described herein again.

Manner 3: The repair module 104 obtains an actual write current of the target phase change storage unit when a write operation is performed. If the actual write current of the target phase change storage unit is greater than or equal to a first current threshold, or is less than or equal to a second current threshold, it is determined that the target phase change storage unit needs to be repaired.

After a plurality of operations on the phase change storage unit, a pulse current of the write operation applied to the phase change storage unit may drift, and may become larger or smaller, instead of keeping a current of the standard write operation pulse unchanged. As a quantity of operations increases, an absolute value of a difference between the actual write current and the current of the standard write operation pulse gradually increases. When the actual write current increases to the first current threshold or decreases to the second current threshold, the repair module 104 may determine that the phase change storage unit needs to be repaired.

The first current threshold and the second current threshold may be determined based on a current (for example, the current of the standard write operation pulse) of the target phase change storage unit when the standard write operation pulse is applied to the target phase change storage unit. For example, if the current of the target phase change storage unit when the standard write operation pulse is applied to the target phase change storage unit is I_{w}, and a pre-configured current drift coefficient is m, the first current threshold may be (1+m)I_{w}, and the second current threshold may be (1−m)I_{w}. For another example, if the current of the target phase change storage unit when the standard write operation pulse is applied to the target phase change storage unit is I_{w}, and a pre-configured current drift value is M, the first current threshold may be I_{w}+M, and the second current threshold may be I_{w}−M. A value selection manner of the current drift coefficient m or the current drift value M is similar to the value selection manner of the voltage drift coefficient x or the voltage drift value X. Details are not described herein again.

Manner 4: The repair module 104 obtains an actual erase current of the target phase change storage unit when an erase operation is performed. If the actual erase current of the target phase change storage unit is greater than or equal to a third current threshold, or is less than or equal to a fourth current threshold, it is determined that the target phase change storage unit needs to be repaired.

After a plurality of operations on the phase change storage unit, a pulse current of the erase operation applied to the phase change storage unit may drift, and may become larger or smaller, instead of keeping a current of the standard erase operation pulse unchanged. As a quantity of operations increases, an absolute value of a difference between the actual erase current and the current of the standard erase operation pulse gradually increases. When the actual erase current increases to the third current threshold or decreases to the fourth current threshold, the repair module 104 may determine that the phase change storage unit needs to be repaired.

The third current threshold and the fourth current threshold may be determined based on a current (for example, the current of the standard erase operation pulse) of the target phase change storage unit when the standard erase operation pulse is applied to the target phase change storage unit. For example, if the current of the target phase change storage unit when the standard erase operation pulse is applied to the target phase change storage unit is Iₑ, and a pre-configured current drift coefficient is n, the third current threshold may be (1+n)Iₑ, and the fourth current threshold may be (1−n)Iₑ. For another example, if the current of the target phase change storage unit when the standard erase operation pulse is applied to the target phase change storage unit is Iₑ, and a pre-configured current drift value is N, the third current threshold may be Iₑ+N, and the fourth current threshold may be Iₑ−N. A value selection manner of the current drift coefficient n or the current drift value N is similar to the value selection manner of the voltage drift coefficient x or the voltage drift value X. Details are not described herein again.

Manner 5: The repair module 104 obtains actual write resistance of the target phase change storage unit when a write operation is performed. If the actual write resistance of the target phase change storage unit is greater than or equal to a first resistance threshold, or is less than or equal to a second resistance threshold, it is determined that the target phase change storage unit needs to be repaired.

After a plurality of operations on the phase change storage unit, resistance of the phase change storage unit may drift when a write operation pulse is applied to the phase change storage unit, and may become larger or smaller, instead of keeping standard write resistance (for example, resistance of the target phase change storage unit when the standard write operation pulse is applied to the target phase change storage unit for the first time) unchanged. As a quantity of operations increases, an absolute value of a difference between the actual write resistance and the standard write resistance gradually increases. When the actual write resistance increases to the first resistance threshold or decreases to the second resistance threshold, the repair module 104 may determine that the phase change storage unit needs to be repaired.

The first resistance threshold and the second resistance threshold may be determined based on the standard write resistance. For example, if the resistance of the target phase change storage unit is R_{w} when the standard write operation pulse is applied to the target phase change storage unit, and a pre-configured resistance drift coefficient is p, the first resistance threshold may be (1+p)R_{w}, and the second resistance threshold may be (1−p)R_{w}. For another example, if the resistance of the target phase change storage unit is R_{w} when the standard write operation pulse is applied to the target phase change storage unit, and a pre-configured resistance drift value is P, the first resistance threshold may be R_{w}+P, and the second resistance threshold may be R_{w}−P. A value selection manner of the resistance drift coefficient p or the resistance drift value P is similar to the value selection manner of the voltage drift coefficient x or the voltage drift value X. Details are not described herein again.

Manner 6: The repair module 104 obtains actual erase resistance of the target phase change storage unit when an erase operation is performed. If the actual erase resistance of the target phase change storage unit is greater than or equal to a third resistance threshold, or is less than or equal to a fourth resistance threshold, it is determined that the target phase change storage unit needs to be repaired.

After a plurality of operations on the phase change storage unit, resistance of the phase change storage unit may drift when an erase operation pulse is applied to the phase change storage unit, and may become larger or smaller, instead of keeping standard erase resistance (for example, resistance of the target phase change storage unit when the standard erase operation pulse is applied to the target phase change storage unit for the first time) unchanged. As a quantity of operations increases, an absolute value of a difference between the actual erase resistance and the standard erase resistance gradually increases. When the actual erase resistance increases to the third resistance threshold or decreases to the fourth resistance threshold, the repair module 104 may determine that the phase change storage unit needs to be repaired.

The third resistance threshold and the fourth resistance threshold may be determined based on the standard erase resistance. For example, if the resistance of the target phase change storage unit is Rₑ when the standard erase operation pulse is applied to the target phase change storage unit for the first time, and a pre-configured resistance drift coefficient is q, the third resistance threshold may be (1+q)Rₑ, and the fourth resistance threshold may be (1−q)Rₑ. For another example, if the resistance of the target phase change storage unit is Rₑ when the standard erase operation pulse is applied to the target phase change storage unit, and a pre-configured resistance drift value is Q, the third resistance threshold may be Rₑ+Q, and the fourth resistance threshold may be Rₑ−Q. A value selection manner of the resistance drift coefficient q or the resistance drift value Q is similar to the value selection manner of the voltage drift coefficient x or the voltage drift value X. Details are not described herein again.

In another possible implementation, the first parameter value may alternatively be a quantity of operations on the target phase change storage unit, and correspondingly, the preset parameter value is a preset threshold of the quantity of operations. In other words, the repair module 104 obtains the quantity of operations on the phase change storage unit, compares the obtained quantity of operations with the preset threshold of the quantity of operations, and determines, based on a result of comparison, whether the phase change storage unit needs to be repaired. The quantity of operations may be a quantity of write operations, may be a quantity of erase operations, or may be a sum of the quantity of write operations and the quantity of erase operations.

For example, if the sum of the quantity of write operations and the quantity of erase operations reaches a first preset quantity of times, it is determined that the target phase change storage unit needs to be repaired; alternatively, if the quantity of write operations reaches a second preset quantity of times, it is determined that the target phase change storage unit needs to be repaired; alternatively, if the quantity of erase operations reaches a third preset quantity of times, it is determined that the target phase change storage unit needs to be repaired.

That a fatigue failure occurs in the phase change storage unit is positively correlated with the quantity of write operations and the quantity of erase operations performed on the phase change storage unit. In other words, the greater the quantity of write operations and the quantity of erase operations performed, the higher a probability that the fatigue failure occurs in the phase change storage unit. In an example, in this implementation, it may be determined, based on the quantity of write operations and/or the quantity of erase operations performed on the target phase change storage unit, whether the target phase change storage unit needs to be repaired.

Optionally, after repeated operation experiments on the phase change storage unit, an average quantity of operations (including the quantity of write operations and the quantity of erase operations) when the fatigue failure occurs in the phase change storage unit may be used as the first preset quantity of times; alternatively, an average quantity of write operations when the fatigue failure occurs may be used as the second preset quantity of times; alternatively, an average quantity of erase operations when the fatigue failure occurs may be used as the third preset quantity of times.

Optionally, a value less than the average quantity of operations (including the quantity of write operations and the quantity of erase operations) may alternatively be selected as the first preset quantity of times based on an experiment result, to predict a case in which the fatigue failure occurs in the phase change storage unit. The phase change storage unit is repaired before the fatigue failure occurs, rather than being repaired after the fatigue failure occurs. This helps reduce occurrence of the fatigue failure in the phase change storage unit, thereby helping avoid an impact on a storage system due to a fatigue failure in the phase change storage unit. Similarly, a value less than the average quantity of write operations may also be selected as the second preset quantity of times, and/or a value less than the average quantity of erase operations may be selected as the third preset quantity of times.

The quantity of operations obtained by the repair module 104 may be counted by the repair module 104, may be counted by another module, and then be obtained by the repair module 104 from the another module, or may be reported to the repair module 104 by another module after a counted quantity of times reaches a preset quantity of times.

In addition, this disclosure further provides a possible implementation. The first parameter value may alternatively be a success rate of a pre-operation on the phase change storage unit, and correspondingly, the preset parameter value is a preset success rate threshold. In other words, the repair module 104 obtains the success rate of a pre-operation on the phase change storage unit, compares the obtained success rate of a pre-operation with the preset success rate threshold, and determines, based on a result of comparison, whether the phase change storage unit needs to be repaired.

The pre-operation may include a pre-write operation and/or a pre-erase operation.

The pre-write operation indicates that a pre-write operation pulse is applied to the phase change storage unit to implement a write operation on the phase change storage unit. A voltage (or a current) of the pre-write operation pulse is less than a voltage (or a current) of the standard write operation pulse. For example, the voltage of the standard write operation pulse is V_{w}, the voltage of the pre-write operation pulse is 0.98 V_{w}, and a success rate of the pre-write operation is a success rate of latest 1000 pre-write operations.

The pre-erase operation indicates that a pre-erase operation pulse is applied to the phase change storage unit to implement an erase operation on the phase change storage unit. A voltage (or a current) of the pre-erase operation pulse is less than a voltage (or a current) of the standard erase operation pulse. For example, the voltage of the standard erase operation pulse is Vₑ, the voltage of the pre-erase operation pulse is 0.98 Vₑ, and a success rate of the pre-erase operation is a success rate of latest 1000 pre-erase operations.

The repair module 104 obtains a success rate of the pre-write operation and the pre-erase operation on the target phase change storage unit, and if the success rate is less than or equal to a first success rate threshold, determines that the target phase change storage unit needs to be repaired; or obtains a success rate of the pre-write operation on the target phase change storage unit, and if the success rate of the pre-write operation is less than or equal to a second success rate threshold, determines that the target phase change storage unit needs to be repaired; or obtains a success rate of the pre-erase operation on the target phase change storage unit, and if the success rate of the pre-erase operation is less than or equal to a third success rate threshold, determines that the target phase change storage unit needs to be repaired.

If the pre-write operation pulse and/or the pre-erase operation are/is set properly, when the phase change storage unit does not undergo a fatigue failure or is not close to a fatigue failure, a write operation/an erase operation can be successfully implemented by applying the pre-write operation pulse/the pre-erase operation pulse to the phase change storage unit. If the success rate of the pre-write operation and the pre-erase operation is less than or equal to the first success rate threshold, and/or the success rate of the pre-write operation is less than or equal to the second success rate threshold, and/or the success rate of the pre-erase operation is less than or equal to the third success rate threshold, it indicates that the phase change storage unit may undergo the fatigue failure or be close to the fatigue failure, and needs to be repaired.

The success rate of a pre-operation obtained by the repair module 104 may be counted by the repair module 104, may be counted by another module, and then be obtained by the repair module 104 from the another module, or may be reported to the repair module 104 by another module after a counted success rate is less than or equal to the success rate threshold.

As mentioned above, the repair module 104 has a plurality of implementations to determine whether the target phase change storage unit needs to be repaired. In actual disclosure, the repair module 104 may perform determining according to one or more of the plurality of implementations. For example, the repair module 104 may obtain both the actual write voltage of the target phase change storage unit and the actual erase voltage of the phase change storage unit. When the actual write voltage of the target phase change storage unit is greater than or equal to the first voltage threshold, or is less than or equal to the second voltage threshold; or when the actual erase voltage of the target phase change storage unit is greater than or equal to the third voltage threshold, or is less than or equal to the fourth voltage threshold, it is determined that the target phase change storage unit needs to be repaired. For another example, the repair module 104 may obtain both the quantity of operations on the target phase change storage unit and the success rate of the pre-operation. When the quantity of operations reaches the first preset quantity of times, or when the success rate of the pre-operation is less than or equal to the first success rate threshold, it is determined that the target phase change storage unit needs to be repaired.

To verify effectiveness of the phase change storage apparatus provided in this embodiment of this disclosure for fatigue repair, the applicant uses a plurality of phase change storage units as shown in FIG. 2 to perform a fatigue test. When write, erase, and read operations are performed on these phase change storage units, pulses shown in FIG. 4 are used. A voltage of the standard erase pulse is 3 V, and a pulse width is 100 ns; a voltage of the standard write pulse is 2 V, and a pulse width is 100 ns; and a voltage of the repair pulse is −8 V, and a pulse width is 20 ns.

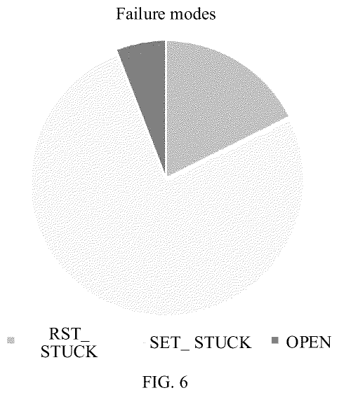

After repeated fatigue operations (for example, write operations and erase operations) on the plurality of phase change storage units, composition of failure modes of the plurality of phase change storage units is shown in FIG. 6. In the phase change storage units, a proportion of rst stuck mode failures is about 60% to 70%, a proportion of set stuck mode failures is about 20% to 30%, and remaining failures are of an open failure mode (for example, open).

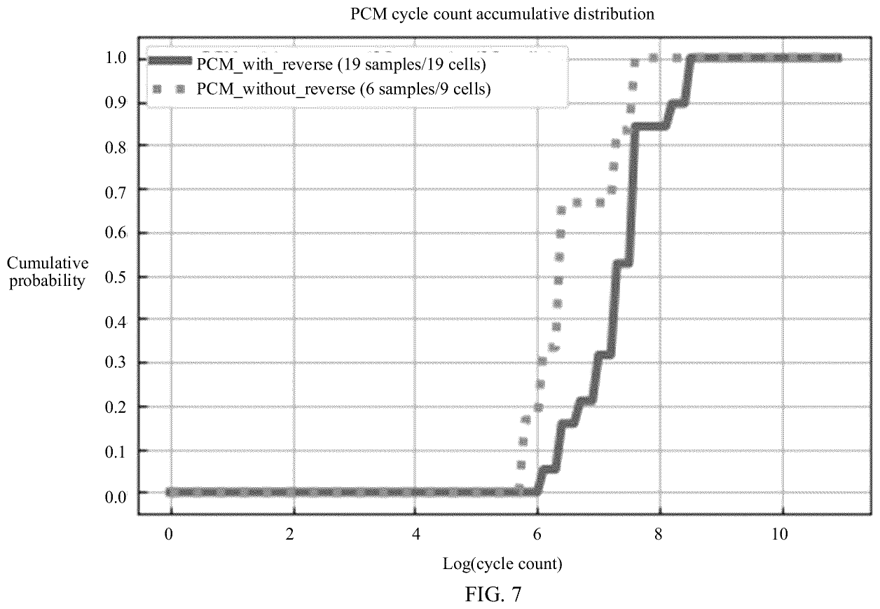

FIG. 7 shows a correspondence between a quantity of fatigue operations and a probability of a failure of a phase change storage unit. A horizontal coordinate x represents that the quantity of fatigue operations is 10^{x}, a vertical coordinate y represents the probability of fatigue failure, and 0≤y≤1. When a repair pulse is not applied, a quantity of fatigue operations and a probability of failures of 100 phase change storage units are shown as the dashed line in FIG. 7. After the repair pulse is applied, the quantity of fatigue operations and the probability of failures of the 100 phase change storage units are shown as the solid line in FIG. 7. It can be learned from the experiment result shown in FIG. 7 that, the phase change storage apparatus provided in this embodiment of this disclosure significantly increases a quantity of fatigue operations on a phase change storage unit, for example, prolongs service life of the phase change storage unit.

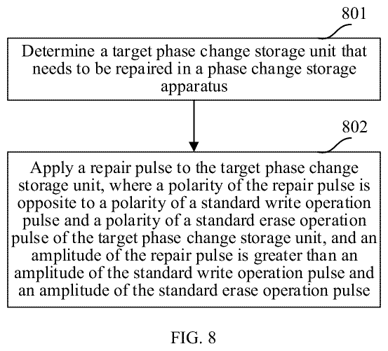

Based on a same technical concept, an embodiment of this disclosure further provides a phase change storage unit repair method. The method may be applied to a phase change storage apparatus. FIG. 8 is a schematic flowchart of a phase change storage unit repair method according to an embodiment of this disclosure. As shown in FIG. 8, the method may include the following steps:

Step 801: Determine a target phase change storage unit that needs to be repaired in the phase change storage apparatus.

The step may be performed by a repair module in the phase change storage apparatus.

When determining the target phase change storage unit that needs to be repaired, there are a plurality of implementations. For details, refer to the implementations of the repair module in the foregoing embodiments.

Step 802: Apply a repair pulse to the target phase change storage unit, where a polarity of the repair pulse is opposite to a polarity of a standard write operation pulse and a polarity of a standard erase operation pulse of the target phase change storage unit, and an amplitude of the repair pulse is greater than an amplitude of the standard write operation pulse and an amplitude of the standard erase operation pulse.

In an example, step 802 may be performed by a pulse generator controlled by the repair module in the phase change storage apparatus.

In the foregoing method embodiments, because the polarity of the repair pulse is opposite to the polarity of the standard write operation pulse and the polarity of the standard erase operation pulse, a failure problem of the set stuck mode can be resolved. In addition, because the amplitude of the repair pulse is greater than the amplitude of the standard write operation pulse and the amplitude of the standard erase operation pulse, and/or the pulse width of the repair pulse is not greater than the pulse width of the standard write operation pulse and the pulse width of the standard erase operation, a failure problem of the rst stuck mode can be resolved. In an example, the foregoing method can resolve both the failure problem of the set stuck mode and the failure problem of the rst stuck mode. For a phase change storage unit array including a plurality of phase change storage units, the failure problem of the set stuck mode and the failure problem of the rst stuck mode, which may occur, can be better resolved. In addition, when the phase change storage unit uses the structure shown in FIG. 3, the repair pulse in this embodiment of this disclosure can further play a role of suppressing Vth threshold drift of the OTS.

Based on the same technical concept, an embodiment of this disclosure further provides a memory chip. The memory chip includes a phase change storage unit array, a control circuit, and a pulse generator. The control circuit is configured to control the pulse generator to perform the method performed in the foregoing method embodiment shown in FIG. 8 on the phase change storage unit array. For related features, refer to the foregoing method embodiment. Details are not described herein again.

An embodiment of this disclosure further provides an electronic device, including a processor and a phase change storage apparatus, where the processor is configured to write data to the phase change storage apparatus or read data from the phase change storage apparatus.

It should be understood that, reference to “an embodiment”, “some embodiments”, or the like described in this specification indicates that one or more embodiments of this disclosure include a specific feature, structure, or characteristic described with reference to the embodiments. Statements such as “in an embodiment”, “in some embodiments”, “in some other embodiments”, and “in other embodiments” that appear at different places in this specification do not necessarily mean referring to a same embodiment. Instead, the statements mean “one or more but not all of embodiments”, unless otherwise emphasized in another manner. The terms “include”, “have”, and their variants all mean “include but are not limited to”, unless otherwise emphasized in another manner.

A person skilled in the art should understand that embodiments of this disclosure may be provided as a method, a system, or a computer program product. In an example, this disclosure may use a form of hardware only embodiments, software only embodiments, or embodiments with a combination of software and hardware. In addition, this disclosure may use a form of a computer program product, for example, may be implemented on one or more computer-usable storage media (including but not limited to a disk memory, a compact disk read-only memory (CD-ROM), an optical memory, and the like) that include computer-usable program code.

This disclosure is described with reference to the flowcharts and/or block diagrams of the method, the device (for example, a system), and the computer program product according to embodiments of this disclosure. It should be understood that computer program instructions may be used to implement each process and/or each block in the flowcharts and/or the block diagrams and a combination of a process and/or a block in the flowcharts and/or the block diagrams. These computer program instructions may be provided for a general-purpose computer, a dedicated computer, an embedded processor, or a processor of any other programmable data processing device to generate a machine, so that the instructions executed by a computer or a processor of any other programmable data processing device generate an apparatus for implementing a function in one or more processes in the flowcharts and/or in one or more blocks in the block diagrams.

These computer program instructions may be stored in a non-transitory computer-readable memory that can instruct the computer or any other programmable data processing device to work in any manner, so that the instructions stored in the non-transitory computer-readable memory generate an artifact that includes an instruction apparatus. The instruction apparatus implements a specific function in one or more processes in the flowcharts and/or in one or more blocks in the block diagrams.

The computer program instructions may alternatively be loaded onto a computer or another programmable data processing device, so that a series of operations and steps are performed on the computer or the another programmable device, so that computer-implemented processing is generated. In an example, the instructions executed on the computer or the another programmable device provide steps for implementing a function in one or more procedures in the flowcharts and/or in one or more blocks in the block diagrams.

Although embodiments of this disclosure have been described, changes and modifications are made to these embodiments. In an example, the appended claims are intended to be construed as including the foregoing embodiments and all changes and modifications falling within the scope of this disclosure.

A person skilled in the art can make various modifications and variations to embodiments of this disclosure without departing from the spirit and scope of embodiments of this disclosure. This disclosure is intended to cover these modifications and variations of embodiments of this disclosure provided that they fall within the scope of protection defined by the following claims and their equivalent technologies.

1. A repair method comprising:
determining a target phase change storage unit that is in a phase change storage apparatus and that needs to be repaired; and
applying a repair pulse to the target phase change storage unit,
wherein a first polarity of the repair pulse is opposite to a second polarity of a standard write operation pulse of the target phase change storage unit and opposite to a third polarity of a standard erase operation pulse of the target phase change storage unit,
wherein a first amplitude of the repair pulse is greater than a second amplitude of the standard write operation pulse and a third amplitude of the standard erase operation pulse, and
wherein a first pulse width of the repair pulse is not greater than a second pulse width of the standard write operation pulse and a third pulse width of the standard erase operation pulse.

2. The repair method of claim 1, wherein the determining comprises:
obtaining a first parameter value of the target phase change storage unit;
comparing the first parameter value with a preset parameter value; and
determining that the target phase change storage unit needs to be repaired when a result of the comparing satisfies a repair condition.

3. The repair method of claim 2, wherein the first parameter value is an electrical parameter value when a write operation or an erase operation is performed on the target phase change storage unit, and wherein the preset parameter value is a preset electrical parameter threshold.

4. The repair method of claim 3, wherein the electrical parameter value is a write voltage, a write current, or a first resistance when the write operation is performed, or the electrical parameter value is an erase voltage, an erase current, or a second resistance when the erase operation is performed.

5. The repair method of claim 2, wherein the first parameter value is a success rate of a pre-operation on the target phase change storage unit, wherein the preset parameter value is a preset success rate threshold, wherein the pre-operation comprises at least one of a pre-write operation or a pre-erase operation, wherein the pre-write operation indicates a write operation on the phase change storage unit based on a pre-write operation pulse, wherein a first voltage of the pre-write operation pulse is less than a second voltage of the standard write operation pulse, wherein the pre-erase operation indicates an erase operation performed on the phase change storage unit based on a third voltage of the pre-erase operation, and wherein the third voltage is based on a fourth voltage of the standard erase operation and is less than the fourth voltage.

6. The repair method of claim 2, wherein the first parameter value is a quantity of operations on the target phase change storage unit, and wherein the preset parameter value is a preset threshold of the quantity of operations.

7. The repair method of claim 6, wherein the operations comprises write operations, erase operations, or a sum of the write operations and the erase operations.

8. A phase change storage apparatus, comprising:
a phase change storage unit array;
a selector;
a pulse generator; and
a repairer configured to:
determine a target phase change storage unit that is in the phase change storage unit array and that needs to be repaired;
select the target phase change storage unit using the selector; and
control the pulse generator to apply a repair pulse to the target phase change storage unit,
wherein a first polarity of the repair pulse is opposite to a second polarity of a standard write operation pulse of the target phase change storage unit and opposite to a third polarity of a standard erase operation pulse of the target phase change storage unit,
wherein a first amplitude of the repair pulse is greater than a second amplitude of the standard write operation pulse and a third amplitude of the standard erase operation pulse, and
wherein a first pulse width of the repair pulse is not greater than a second pulse width of the standard write operation pulse and a third pulse width of the standard erase operation pulse.

9. The phase change storage apparatus of claim 8, wherein the repairer is configured to determine the target phase change storage unit by:
obtaining a first parameter value of the target phase change storage unit;
comparing the first parameter value with a preset parameter value; and
determining that the target phase change storage unit needs to be repaired when a result of the comparing satisfies a repair condition.

10. The phase change storage apparatus of claim 9, wherein the first parameter value is an electrical parameter value when a write operation or an erase operation is performed on the target phase change storage unit, and wherein the preset parameter value is a preset electrical parameter threshold.

11. The phase change storage apparatus of claim 10, wherein the electrical parameter value is a write voltage, a write current, or a first resistance when the write operation is performed, or the electrical parameter value is an erase voltage, an erase current, or a second resistance when the erase operation is performed.

12. The phase change storage apparatus of claim 9, wherein the first parameter value is a first success rate of a pre-operation on the target phase change storage unit, wherein the preset parameter value is a preset success rate threshold, wherein the first success rate comprises at least one of a second success rate of a pre-write operation or a third success rate of a pre-erase operation, wherein the pre-write operation indicates a write operation performed on the target phase change storage unit based on a pre-write operation pulse, wherein a first voltage of the pre-write operation pulse is less than a second voltage of the standard write operation pulse, wherein the pre-erase operation indicates an erase operation performed on the target phase change storage unit based on a third voltage of the pre-erase operation, and wherein the third voltage is based on a fourth voltage of the standard erase operation and is less than the fourth voltage.

13. The phase change storage apparatus of claim 9, wherein the first parameter value is a quantity of operations on the target phase change storage unit, and wherein the preset parameter value is a preset threshold of the quantity of operations.

14. The phase change storage apparatus of claim 13, wherein the operations comprises write operations, erase operations, or a sum of the write operations and erase operations.

15. An electronic device, comprising:
a phase change storage apparatus comprising:
a phase change storage unit array;
a selector;
a pulse generator; and
a repairer configured to:
determine a target phase change storage unit that is in the phase change storage unit array and that needs to be repaired;
select the target phase change storage unit using the selector; and
control the pulse generator to apply a repair pulse to the target phase change storage unit, wherein a first polarity of the repair pulse is opposite to a second polarity of a standard write operation pulse of the target phase change storage unit and a third polarity of a standard erase operation pulse of the target phase change storage unit, wherein a first amplitude of the repair pulse is greater than a second amplitude of the standard write operation pulse and a third amplitude of the standard erase operation pulse, and wherein a first pulse width of the repair pulse is not greater than a second pulse width of the standard write operation pulse and a third pulse width of the standard erase operation pulse; and
a processor coupled to the phase change storage apparatus and configured to write data to the phase change storage apparatus or read data from the phase change storage apparatus.

16. The electronic device of claim 15, wherein the repairer is configured to determine the target phase change storage unit by:
obtaining a first parameter value of the target phase change storage unit;
comparing the first parameter value with a preset parameter value; and
determining that the target phase change storage unit needs to be repaired when a result of the comparing satisfies a repair condition.

17. The electronic device of claim 16, wherein the first parameter value is an electrical parameter value when a write operation or an erase operation is performed on the target phase change storage unit, and wherein the preset parameter value is a preset electrical parameter threshold.

18. The electronic device of claim 17, wherein the electrical parameter value is a write voltage, a write current, or a first resistance when the write operation is performed, or the electrical parameter value is an erase voltage, an erase current, or a second resistance when the erase operation is performed.

19. The electronic device of claim 16, wherein the first parameter value is a first success rate of a pre-operation on the target phase change storage unit, wherein the preset parameter value is a preset success rate threshold, wherein the first success rate comprises at least one of a second success rate of a pre-write operation or a third success rate of a pre-erase operation, wherein the pre-write operation indicates a write operation performed on the target phase change storage unit based on a pre-write operation pulse, wherein a first voltage of the pre-write operation pulse is less than a second voltage of the standard write operation pulse, wherein the pre-erase operation indicates an erase operation performed on the target phase change storage unit based on a third voltage of the pre-erase operation, and wherein the third voltage is based on a fourth voltage of the standard erase operation and is less than the fourth voltage.

20. The electronic device of claim 16, wherein the first parameter value is a quantity of operations on the target phase change storage unit, and wherein the preset parameter value is a preset threshold of the quantity of operations.
